(19) United States
(12) Patent Application Publication
(10) Pub. No.: US 2025/0035719 A1
(43) Pub. Date: Jan. 30, 2025

(54) METHOD AND APPARATUS WITH MAGNETIC BODY MEASUREMENT

(71) Applicants: Samsung Electronics Co., Ltd., Suwon-si (KR); Seoul National University R&DB Foundation, Seoul (KR)

(72) Inventors: Jae Sung YOON, Seoul (KR); Sug Bong CHOE, Seoul (KR)

(73) Assignees: Samsung Electronics Co., Ltd., Suwon-si (KR); Seoul National University R&DB Foundation, Seoul (KR)

(21) Appl. No.: 18/647,745

(22) Filed: Apr. 26, 2024

(30) Foreign Application Priority Data
Jul. 27, 2023 (KR) 10-2023-0098381

(51) Int. Cl. G01R 33/12; G01N 27/04; G01N 27/72; G01R 27/16

(52) U.S. Cl. CPC G01R 33/12; G01N 27/041; G01N 27/72; G01R 27/16

(57) ABSTRACT

A method and apparatus for measuring properties of a magnetic body are provided. The method includes applying a uniform magnetic field to generate a magnetic space; rotating a magnetic body in the magnetic space about a predetermined axis; measuring a first resistance value; measuring a second resistance value; and calculating a magnetic anisotropy constant of the magnetic body, based on the first and second resistance values, wherein the first resistance value is a measured resistance value of the magnetic body according to a magnetic field sweep in a direction of a magnetization hard axis of the magnetic body, and wherein the second resistance value is another measured resistance value of the magnetic body according to an angle of an external magnetic field, the angle of the external magnetic field being an angle formed by a magnetization easy axis of the magnetic body and a direction of the uniform magnetic field applied to the magnetic body.

### CROSS-REFERENCE TO RELATED APPLICATIONS

This application claims the benefit under 35 USC § 119 (a) of Korean Patent Application No. 10-2023-0098381, filed on Jul. 27, 2023, in the Korean Intellectual Property Office, the entire disclosure of which is incorporated herein by reference for all purposes.

### BACKGROUND

### 1. Field

The following description relates to a method and apparatus with magnetic body measurement.

### 2. Description of Related Art

Spintronics is one of the candidates for producing next-generation memories or logical storage devices. Example storage devices may include magnetic random access memory (M-RAM) using spin-transfer torque or spin-orbit torque and racetrack memory using a domain wall, skyrmion, etc., and may be configured to allow reading or writing of data using a magnetization state, a magnetic chiral structure, etc. In order to do that, each device may essentially include a ferromagnetic body layer, the thickness of which is usually several angstroms (Å). Thus, it is important to accurately measure the physical properties of the ferromagnetic body so as to produce a more sophisticated and high-quality storage device. In particular, a magnetic anisotropy constant of a magnetic body is a value representing the basic properties of the magnetic body and is important data that determines the properties of the magnetic body.

Moreover, a size of such a storage device required for commercialization continues to become very small, but the existing technology of measuring physical properties of a ferromagnetic body becomes unusable below a certain size as a measurement signal becomes very small.

The above description is information the inventor(s) acquired during the course of conceiving the present disclosure, or already possessed at the time, and is not necessarily art publicly known before the present application was filed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method includes applying a uniform magnetic field to generate a magnetic space; rotating a magnetic body in the magnetic space about a predetermined axis; measuring a first resistance value; measuring a second resistance value; and calculating a magnetic anisotropy constant of the magnetic body, based on the first and second resistance values, wherein the first resistance value is a measured resistance value of the magnetic body according to a magnetic field sweep in a direction of a magnetization hard axis of the magnetic body, and wherein the second resistance value is another measured resistance value of the magnetic body according to an angle of an external magnetic field, the angle of the external magnetic field being an angle formed by a magnetization easy axis of the magnetic body and a direction of the uniform magnetic field applied to the magnetic body.

The calculating of the magnetic anisotropy constant of the magnetic body may include determining a saturation parameter based on the first resistance value; determining a magnetism-based parameter based on the second resistance value; and determining the magnetic anisotropy constant of the magnetic body based on the saturation parameter and the magnetism-based parameter.

The determining of the saturation parameter may include determining the saturation parameter based on a gradient in a section where the first resistance value is unsaturated.

The determining of the magnetism-based parameter may include determining the magnetism-based parameter based on a gradient in a section determined based on the magnetization easy axis of the magnetic body.

The method may further include the measuring of the second resistance value according to the angle of the external magnetic field in a state in which a magnitude of the external magnetic field may be fixed.

The magnetic anisotropy constant of the magnetic body may be obtained by multiplying the fixed magnitude of the external magnetic field and the second parameter to generate a first value; multiplying the fixed magnitude of the external magnetic field and the first parameter to generate a second value; subtracting the second parameter from the second value to generate a third value; and dividing the first value by the third value.

The method may further include the measuring of the first resistance value by supplying a predetermined current to the magnetic body through electrodes of first both ends of the magnetic body in a direction of the predetermined axis; measuring, according to the magnetic field sweep, a first voltage value of the magnetic body through electrodes of second both ends of the magnetic body in a direction perpendicular to the predetermined axis; and determining the first resistance value based on a current value supplied to the magnetic body and the measured first voltage value of the magnetic body.

The method may further include performing the measuring of the second resistance value by supplying a predetermined current to the magnetic body through electrodes of first both ends of the magnetic body in a direction of the predetermined axis; measuring, according to the angle of the external magnetic field, a second voltage value of the magnetic body through electrodes of second both ends of the magnetic body in a direction perpendicular to the predetermined axis; and determining the second resistance value based on a current value supplied to the magnetic body and the measured second voltage value of the magnetic body.

The magnetic body, with an in-plane magnetic anisotropy (IMA), may include an ultra-thin film having a thickness of 1 nanometer (nm) or less.

As an example, a non-transitory computer-readable storage medium storing instructions that, when executed by a processor, may cause the processor to perform the method.

In another general aspect, an apparatus includes a magnetic field generator configured to generate a magnetic space by applying a uniform magnetic field; a rotating driver configured to rotate the magnetic body about a predetermined axis in the magnetic space; a data measurement device configured to measure a first resistance value and a second resistance value; and a calculator configured to determine the magnetic anisotropy constant of the magnetic body based on the first resistance value and the second resistance value, wherein the first resistance value is a measured resistance value of the magnetic body according to a magnetic field sweep in a direction of a magnetization hard axis of the magnetic body, and wherein the second resistance value is another measured resistance value of the magnetic body according to an angle of an external magnetic field, the angle of the external magnetic field being an angle formed by a magnetization easy axis of the magnetic body and a direction of a magnetic field applied to the magnetic body.

The calculator may be configured to determine a first parameter based on the first resistance value, determine a second parameter based on the second resistance value, and determine the magnetic anisotropy constant of the magnetic body based on the first parameter and the second parameter.

The calculator may be configured to determine the first parameter based on a gradient in a section where the first resistance value is unsaturated.

The calculator may be configured to determine the second parameter based on a gradient in a section determined based on the magnetization easy axis of the magnetic body.

The calculator may be configured to measure the second resistance value according to the angle of the external magnetic field in a state in which a magnitude of the external magnetic field is fixed.

The calculator may be configured to determine the magnetic anisotropy constant of the magnetic body by multiplying the fixed magnitude of the external magnetic field and the second parameter to obtain a first value; multiplying the fixed magnitude of the external magnetic field and the first parameter to obtain a second value; subtracting the second parameter from the second value to obtain a third value; and dividing the first value by the third value.

The data measurement device may be configured to supply a predetermined current to the magnetic body through electrodes of first both ends of the magnetic body in a direction of the predetermined axis; measure, according to the magnetic field sweep, a first voltage value of the magnetic body through electrodes of second both ends of the magnetic body in a direction perpendicular to the predetermined axis; and determine the first resistance value based on a current value supplied to the magnetic body and the measured first voltage value of the magnetic body.

The data measurement device may be configured to supply a predetermined current to the magnetic body through electrodes of first both ends of the magnetic body in a direction of the predetermined axis; measure, according to the angle of the external magnetic field, a second voltage value of the magnetic body through electrodes of second both ends of the magnetic body in a direction perpendicular to the predetermined axis; and determine the second resistance value based on a current value supplied to the magnetic body and the measured second voltage value of the magnetic body.

The magnetic body, with an in-plane magnetic anisotropy (IMA), may include an ultra-thin film having a thickness of 1 nanometer (nm) or less.

In another general aspect, an electronic device includes one or more processors configured to execute instructions; and one or more memories storing the instructions, wherein the execution of the instructions by the one or more processors configures the one or more processors to generate a first resistance value of a magnetic body according to a magnetic field sweep in a direction of a magnetization hard axis of the magnetic body; generate a second resistance value of the magnetic body according to an angle of an external magnetic field, the angle of the external magnetic field being an angle formed by a magnetization easy axis of the magnetic body and a direction of a magnetic field applied to the magnetic body; and determine a magnetic anisotropy constant of the magnetic body based on the first resistance value and the second resistance value.

Other features and aspects will be apparent from the following detailed description, the drawings, and the claims.

### BRIEF DESCRIPTION OF THE DRAWINGS

FIG. 1 illustrates an example configuration of an apparatus with magnetic anisotropy constant measurement according to one or more embodiments.

FIGS. 2A and 2B illustrate example methods with magnetic anisotropy constant measurement according to one or more embodiments.

FIG. 3 illustrates an example Taylor's coefficient according to an H/|H_{K}| value.

FIG. 4A illustrates an example measurement result of a magnetic field sweep in the direction of a magnetization hard axis according to one or more embodiments.

FIG. 4B illustrates an example measurement result of rotation near a magnetization easy axis according to one or more embodiments.

FIG. 5 illustrates an example measurement result of a magnetic anisotropy constant according to one or more embodiments.

FIG. 6 illustrates an example method with magnetic anisotropy constant determination according to one or more embodiments.

FIG. 7 illustrates an example configuration of an electronic device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing. It is to be understood that if a component (e.g., a first component) is referred to, with or without the term “operatively” or “communicatively,” as “coupled with,” “coupled to,” “connected with,” or “connected to” another component (e.g., a second component), it means that the component may be coupled with the other component directly (e.g., by wire), wirelessly, or via a third component.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein.

An electronic device, according to various embodiments, may be various types of products, such as, for example, a personal computer (PC), a laptop computer, a tablet computer, a smartphone, a television (TV), a smart home appliance, an intelligent vehicle, a kiosk, and a wearable device, as non-limiting examples.

In the case of a thin film of a ferromagnetic body, there may exist an axis in which magnetization is easily aligned, and conversely, there may exist an axis in which magnetization is not easily aligned, and such axes may be typically referred to as a magnetization easy axis and a magnetization hard axis, respectively. The energy difference required to align magnetization direction from a magnetization easy axis to a magnetization hard axis may be referred to as magnetic anisotropy energy, and the magnitude of a magnetic field required for the alignment may be referred to as a magnetic anisotropy constant (H_{K}).

An existing approach of measuring the magnetic anisotropy constant may use a vibrating sample magnetometer (VSM), where a sample to be measured may be vibrated at a specific frequency, and a voltage induced in a nearby pickup coil may be measured, such that a magnetic moment of the sample may be measured to obtain a magnetic field to magnetic anisotropy energy (M-H) curve. By measuring the M-H curve on a magnetization hard axis, the magnetic anisotropy constant may be obtained from a point at which a magnetic moment no longer increases and becomes saturated.

However, in this existing approach of using the VSM, the magnitude of an applicable external magnetic field needs to be at least greater than the magnetic anisotropy constant of a sample to be measured, and due to limitations in measurement resolution, this existing approach using the VSM cannot measure the physical properties of a ferromagnetic body when the ferromagnetic body is an ultra-thin film (e.g., an ultra-thin film having a thickness of less than 1 nanometer (nm)) or when the device including a ferromagnetic body layer is a micro-sized or nano-sized device. For example, a typical VSM has resolution of approximately up to 10⁻⁹ electromagnetic units (emu). Considering that a representative ferromagnetic body (e.g., iron (Fe), carbon monoxide (Co), nickel (Ni), etc.) is M_{S}˜10⁶ ampere per meter (A/m), if the volume of the thin film is assumed to be approximately up to {1 centimeter (cm)*1 cm*1 nm}, the thin film should be expected to have a value of about up to 10-10 emu, and thus, an ultra-thin film of the ferromagnetic body with the thickness of less than 1 nm may be difficult to be measured with the VSM. In addition, according to the measurement principle of the VSM, the magnitude of an external magnetic field essentially needs to be greater than or equal to the magnetic anisotropy constant in the direction of the magnetization hard axis to measure the magnetic anisotropy. Therefore, if the magnetic anisotropy constant is greater than the magnitude of an applicable external magnetic field, it may be impossible to measure the magnetic anisotropy constant.

Another existing approach of measuring a magnetic anisotropy constant is to electrically measure the magnetic anisotropy constant when a magnetization easy axis of a thin film of a ferromagnetic body is perpendicular to the thin film (a perpendicular magnetic anisotropy (PMA)). Such an approach is based on Hall effect measurement, which is a method of measuring a voltage in the direction perpendicular to the direction of an applied current. When such a measurement approach is applied to the ferromagnetic body, the Hall voltage measured by an anomalous Hall effect (AHE) may have a relationship of V_{H}˜R_{AHE}IM_{z}=R_{AHE}IM_{S} cos θ. Such a relationship may identify how much the magnetization direction is tilted according to the magnitude of an external magnetic field applied. Here, R_{AHE} denotes an anomalous Hall resistance, I denotes an applied current, M_{z} denotes a z-direction component of magnetization, and θ denotes an angle at which magnetization is tilted from a z-axis. However, this approach may be applicable only when a device has a PMA and it is difficult to apply when a device has an in-plane magnetic anisotropy (IMA).

As a non-limiting example, one or more embodiments may include a method of measuring a magnetic anisotropy constant, for a magnetic body having an IMA as a non-limiting example, that is applicable even to a micro-sized device and that is measurable with a magnetic field of less than or equal to the magnetic anisotropy constant.

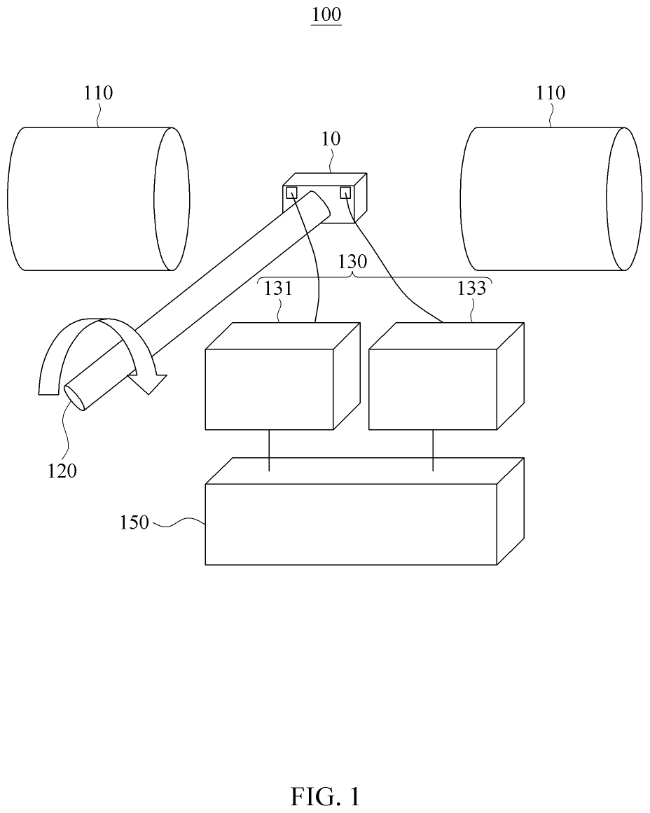

FIG. 1 illustrates an example configuration of a magnetic anisotropy constant measurement device according to one or more embodiments.

Referring to FIG. 1, an example apparatus 100 with magnetic anisotropy constant measurement may include a magnetic field generator 110, a rotation driver 120, a data measurement device 130, and a calculator 150. The term “module” may be a unit including one or a combination of two or more of hardware, software, and firmware. The term “module” may interchangeably be used with other terms, for example, “unit,” “logic,” “logical block,” “component,” or “circuit.” The “module” may be a minimum unit of an integrally formed component or part thereof. The “module” may be a minimum unit for performing one or more functions or part thereof. The “module” may be implemented mechanically or electronically. For example, the “module” may include any one or any combination of an application-specific integrated circuit (ASIC) chip, field-programmable gate arrays (FPGAs), or a programmable-logic device that performs known operations or operations to be developed.

The magnetic field generator 110 may be configured to form a magnetic space by applying a uniform magnetic field within a predetermined space.

The rotation driver 120 may be configured to freely rotate a sample 10 about a predetermined axis in the magnetic field generated by the magnetic field generator 110. For example, the sample 10 may be fixed perpendicular to a rotation axis of the rotation driver 120 and then may be rotated 360 degrees about the rotation axis from the direction parallel to the direction of an external magnetic field to the semi-parallel direction.

As non-limiting examples, the sample 10 may be a magnetic body such as a micro-sized IMA ferromagnetic body. The sample 10 may also be a micro-sized thin film. Alternatively, the sample 10 may be a micro-sized device. The calculator 150 may be a processor or other processing circuitry.

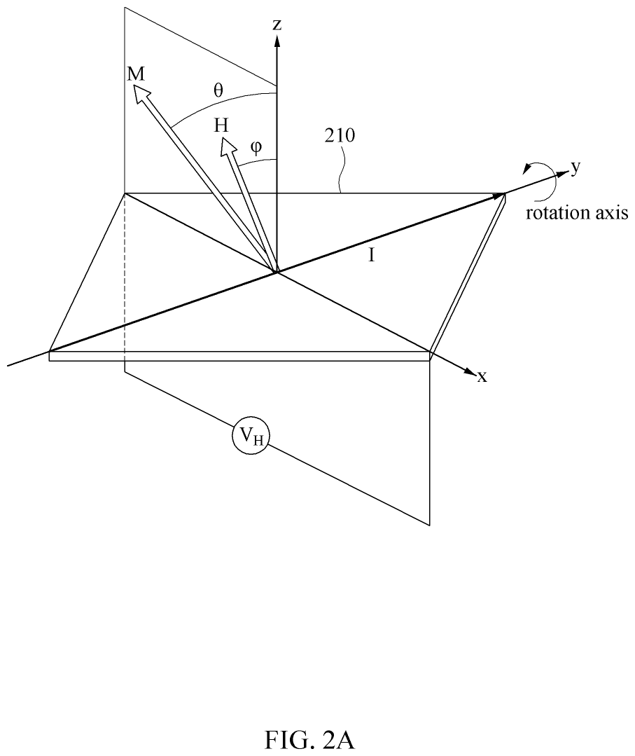

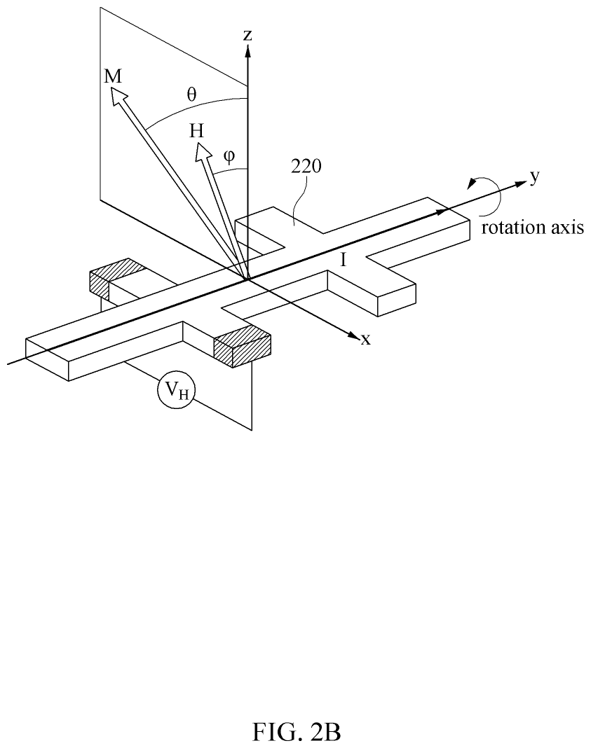

The data measurement device 130 may be configured to include a current source 131 and a voltmeter 133. The current source 131 may be connected to electrodes of first both ends of the sample 10 and may supply a predetermined current to the sample 10 through the electrodes of the first both ends. The voltmeter 133 may be connected to electrodes of second both ends of the sample 10 and may measure the voltage of the sample 10 through the electrodes of the second both ends. The voltmeter 133 may be a nanovoltmeter. As described in detail with reference to FIGS. 2A and 2B below, the voltmeter 133 may measure the voltage of a magnetic body through the electrodes of the second both ends of the sample 10 in the direction perpendicular to the predetermined axis.

Furthermore, the data measurement device 130 may convert the voltage value measured through the voltmeter 133 into a resistance value according to an angle of the external magnetic field. Since a current value supplied to the sample 10 may be identified, the data measurement device 130 may convert the measured voltage value into the resistance value using the principle of Ohm's law (V=IR). In order to convert the measured voltage value into the resistance value, the data measurement device 130 may include a separate data converter. However, the data measurement device 130 is not limited to the configuration of the current source 131, the voltmeter 133, and the data converter, and may include any other configuration that is suitable to measure an electrical resistance of a material.

FIGS. 2A and 2B illustrate example methods with magnetic anisotropy constant measurement according to one or more embodiments.

Referring to FIG. 2A, the apparatus 100 may measure a magnetic anisotropy constant of a thin film 210 with a micro size generated by a deposition process (direct current (DC) magnetron sputtering). For example, the thin film 210 may be samples with a structure of platinum (Pt) (5 nm)/Co (t)/tantalum (Ta) (3 nm) and may be deposited on a silicon dioxide (SiO₂) substrate on silicon (Si). The range of t may be from 1.2 nm to 1.7 nm and measurements may be performed on the total of “6” samples at 0.1 nm intervals.

By using the apparatus 100, a predetermined current may be supplied to the thin film 210 through the electrodes of the first both ends and the voltage of the thin film 210 may be measured through the electrodes of the second both ends. For example, the apparatus 100 may allow a current I to flow in one diagonal direction of the thin film 210 and may measure the Hall voltage V_{H} in the other diagonal direction.

The calculator 150 of the apparatus 100 may determine the magnetic anisotropy constant of the thin film 210 using the measured Hall voltage V_{H}.

Referring to FIG. 2B, the apparatus 100 may measure a magnetic anisotropy constant of a hall bar device 220. The hall bar device 220 is a micro-sized hall bar. For example, the hall bar device 220 may have a width of 4 micrometers (μm) and manufactured in a photolithography method.

By using the apparatus 100, a predetermined current may be supplied to the hall bar device 220 through the electrodes of the first both ends and the voltage of the hall bar device 220 may be measured through the electrodes of the second both ends. For example, the apparatus 100 may allow the current I to flow in one diagonal direction of the hall bar device 220 and may measure the Hall voltage VH in the direction perpendicular to the applied current I.

The calculator 150 of the apparatus 100 may determine the magnetic anisotropy constant of the hall bar device 220 using the measured Hall voltage V_{H}.

Prior to illustrating the calculator 150 of the apparatus 100, the “Stoner-Wohlfarth” theory for obtaining a magnetic anisotropy constant is briefly illustrated.

According to the Stoner-Wohlfarth theory, if an external magnetic field H is applied at an angle φ with a vertical axis of a magnetic thin film, energy E of the magnetic thin film is given as Equation 1.

$$E = - {K}_{U} {cos}^{2} θ - {M}_{S} H cos ( θ - φ ) \qquad Equation 1$$

A first term K_{U} cos² θ on the right side denotes magnetic anisotropy energy, in which K_{U} denotes a magnetic anisotropy constant. A second term M_{S}H cos(θ−φ) denotes a Zeeman energy term. θ denotes an angle formed by the magnetization direction with the vertical axis of the magnetic thin film.

If K_{U}>0, this formula denotes that a magnetic body (e.g., the sample 10 of FIG. 1) is a PMA magnetic body, and if K_{U}<0, this formula denotes that the magnetic body is an IMA magnetic body. Subsequently, if Equation 1 is divided by K_{U} to be normalized, this may be expressed as Equation 2.

$$ε ≡ \frac{E}{{K}_{U}} = - {cos}^{2} θ - 2 ( \frac{H}{{H}_{K}} ) cos ( θ - φ ) \qquad Equation 2$$

A magnetic anisotropy constant H_{K} may be defined as Equation 3.

$${H}_{K} ≡ \frac{2 {K}_{U}}{{M}_{S}} \qquad Equation 3$$

θ_{eq} of an energy balance condition may be obtained from ∂ε/∂θ=0. If a signal of Equation 2 is differentiated with respect to θ, and if an overall value is found to be 0, this is the point where the energy becomes minimum and thus the relationship between all variables may be determined. If Equation 2 is differentiated, it may be expressed as the following equation.

$$sin 2 {θ}_{eq} + 2 ( H / {H}_{K} ) sin ( {θ}_{eq} - φ ) = 0 \qquad Equation 4$$

Equation 4 may be solved for the following two experimental conditions, which are a magnetic field sweep condition where a magnetic field sweep in the direction of the magnetization hard axis is measured and a rotational condition where rotation near the magnetization easy axis is measured.

Considering the magnetic field sweep condition that the magnetic body is an IMA magnetic body, the equation φ=0 may be established and therefore, Equation 4 may be expressed as Equation 5.

$$sin {θ}_{eq} ( cos {θ}_{eq} + \frac{H}{{H}_{K}} ) = 0 \qquad Equation 5$$

In Equation 5, a non-trivial solution is given as cos θ_{eq}=H/|H_{K}|, and it may be noted that the magnetic body is an IMA magnetic body and thus, the equation H_{K}=−|H_{K}| may be established. However, since the equation R_{H}=R_{AHE} cos θ_{eq} establishes, in an area where |H|≤|H_{K}|, Equation 6 below may be satisfied.

$${R}_{H} ( H , φ = 0 ) = α H \qquad Equation 6$$

In Equation 6, a denotes a linear coefficient. α may be defined as Equation 7 and may be referred to as a first parameter below.

$$α ≡ \frac{{R}_{AHE}}{\vert {H}_{K} \vert}$$

The process of obtaining a solution for the rotation measurement near the magnetization easy axis in the rotational condition is as follows. Since the magnetic body is an IMA magnetic body, the magnetization easy axis may become θ_{eq}=±π/2. Therefore, the nearness of the magnetization easy axis may be defined as in Equation 7.

$${θ}_{eq} = δθ \pm \frac{π}{2} , \qquad Equation 7$$

$$φ = δφ \pm \frac{π}{2}$$

In Equation 7, δθ and δφ may denote micro angular displacement from the magnetization easy axis. If δθ and δφ are substituted back into Equation 4, a result as Equation 8 may be obtained.

$$- sin 2 δ θ - 2 ( {H}_{0} / \vert {H}_{K} \vert ) sin ( δθ - δ φ ) = 0 \qquad Equation 8$$

In Equation 8, H₀ denotes a magnitude of a fixed external magnetic field.

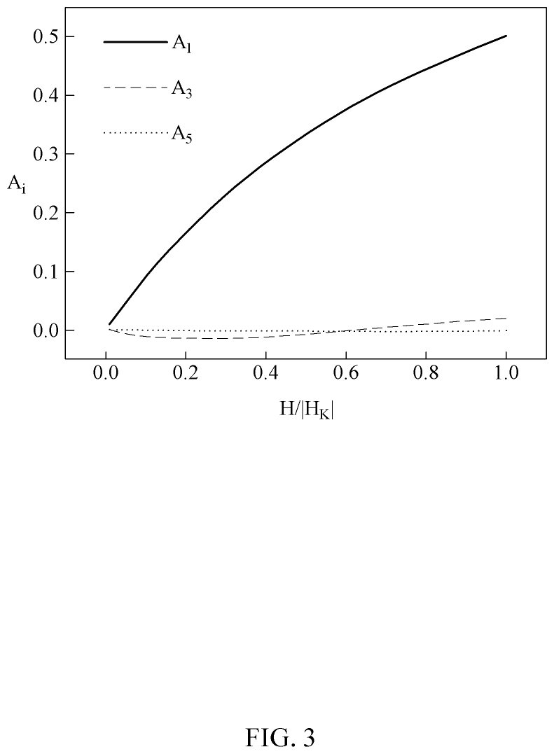

FIG. 3 illustrates an example Taylor's coefficient according to an H/|H_{K}| value.

If Equation 8 is expanded with respect to φ by the Taylor's expansion (that is, if the equation sin δθ=A₁δφ+A₃δφ³+A₅δφ⁵+ . . . is established), a result of calculating each coefficient with respect to H/|H_{K}| may be one as shown in FIG. 3.

Referring to FIG. 3, A₁ may have a significantly greater value than other higher-order term coefficients A3 and A5 as a non-limiting example. Therefore, Equation 8 may be rewritten as Equation 9 once again.

$$sin δθ ≅ {A}_{1} δ φ = \frac{{H}_{0}}{\vert {H}_{K} \vert + {H}_{0}} δ φ \qquad Equation 9$$

In addition, if the relationship of θ_{eq}=δθ±π/2 and sin δθ==∓cos θ_{eq} is used, a relationship as shown in Equation 10 may be obtained.

$$cos {θ}_{eq} ≅ ∓ \frac{{H}_{0}}{\vert {H}_{K} \vert + {H}_{0}} δ φ \qquad Equation 10$$

If the relationship of R_{H}=R_{AHE} cos θ_{eq} is used once again, this may be expressed as Equation 11.

$${R}_{H} ( {H}_{0} , φ = δ φ \pm \frac{π}{2} ) = ∓ βδφ \qquad Equation 11$$

A linear coefficient β may be defined as Equation 12 and may be referred to as a second parameter below.

$$β ≡ \frac{{R}_{AHE} {H}_{0}}{\vert {H}_{K} \vert + {H}_{0}} \qquad Equation 12$$

If Equations 6 and 12 are combined, |H_{K}| may be expressed as Equation 13.

$$\vert {H}_{K} \vert = \frac{β {H}_{0}}{α {H}_{0} - β} \qquad Equation 13$$

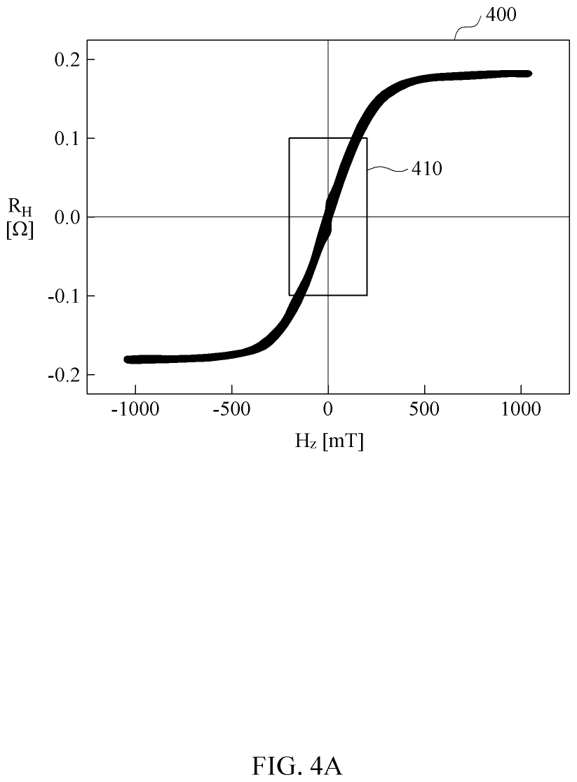

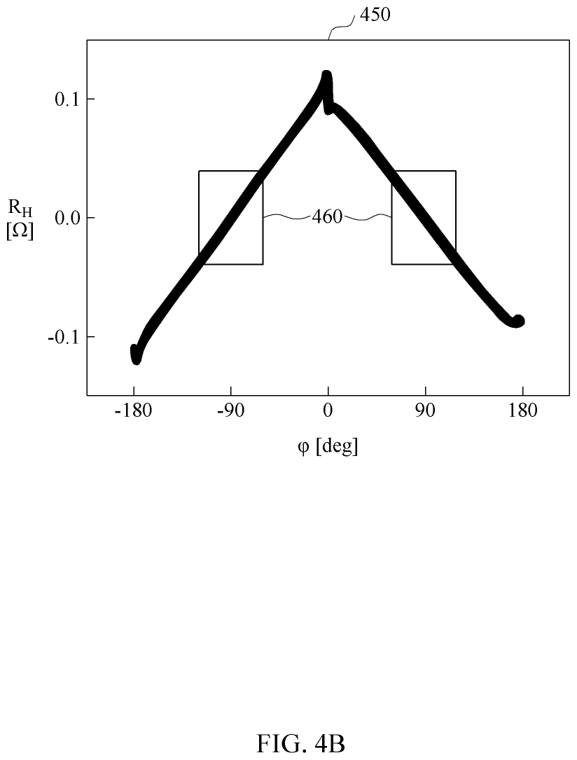

Referring to Equation 13, if α and β are measured, a value of |H_{K}| may be obtained. A method of measuring α and β is described below with reference to FIGS. 4A and 4B.

FIG. 4A illustrates an example measurement result of a magnetic field sweep in the direction of a magnetization hard axis.

Referring to FIG. 4A, an example graph 400 illustrates a measurement result of a resistance value of a magnetic body (e.g., the sample 10 of FIG. 1) according to a magnetic field sweep in the direction of a magnetization hard axis of the magnetic body. The apparatus 100 may measure a voltage value of the magnetic body according to the magnetic field sweep through a voltmeter (e.g., the voltmeter 133 of FIG. 1) and may convert the measured voltage value into the resistance value. A gradient of the graph 400 may be the linear coefficient α of Equation 6. Accordingly, the calculator 150 of the apparatus 100 may obtain the graph 400 by receiving the resistance value of the magnetic body according to the magnetic field sweep measured by a data measurement module (e.g., the data measurement module 130 of FIG. 1), and the gradient may be calculated in the graph 400 to obtain the first parameter α of Equation 6.

FIG. 4B illustrates an example measurement result of rotation near a magnetization easy axis.

Referring to FIG. 4B, an example graph 450 illustrates a measurement result of a resistance value of a magnetic body (e.g., the sample 10 of FIG. 1) according to an angle of an external magnetic field, which is an angle formed by a magnetization easy axis of the magnetic body and the direction of a magnetic field applied to the magnetic body. The apparatus 100 may measure a voltage value of the magnetic body according to the angle of the external magnetic field in a state in which the magnitude of the external magnetic field is fixed through a voltmeter (e.g., the voltmeter 133 of FIG. 1) and may convert the measured voltage value into the resistance value. A gradient of the graph 450 may be the linear coefficient β of Equation 12. The calculator 150 of the apparatus 100 may obtain the graph 450 by receiving the resistance value of the magnetic body according to the magnetic field sweep measured by a data measurement module (e.g., the data measurement module 130 of FIG. 1), and the gradient may be calculated in the graph 450 to obtain the second parameter β of Equation 12.

The calculator 150 of the apparatus 100 may determine a magnetic anisotropy constant using the first parameter and the second parameter according to Equation 12.

Furthermore, referring to the graph 400, the first parameter may be obtained only by measuring an area (e.g., a first area 410) where |H|≤|H_{K}|, and referring to the graph 450, the second parameter may be obtained only by measuring an area (e.g., a second area 460) where |H|≤|H_{K}|. Accordingly, the apparatus 100 may be sufficient to obtain the magnetic anisotropy constant by simply measuring the first and second areas 410 and 460 where |H|≤|H_{K}|.

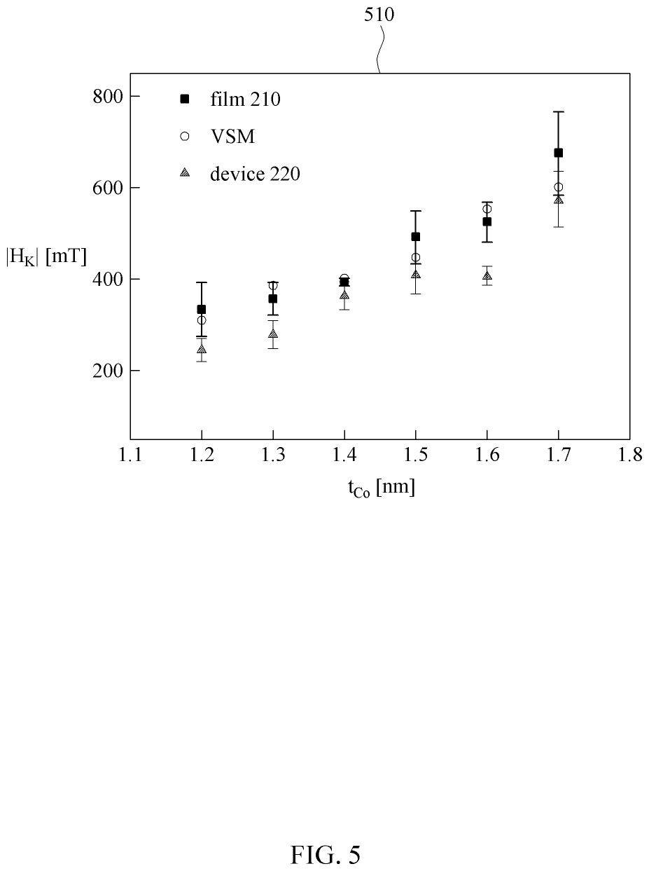

FIG. 5 illustrates an example measurement result of a magnetic anisotropy constant.

Referring to FIG. 5, an example graph 510 illustrates together a magnetic anisotropy constant of the thin film 210 of a quadrangle with a magnitude of 12 millimeters (mm)*12 mm measured according to the method of FIG. 2A, a magnetic anisotropy constant of the device 220 measured according to the method of FIG. 2B, and a magnetic anisotropy constant with respect to a thickness t of Co measured by using a VSM.

Referring to the graph 510, the thin film 210 may closely correspond with a result obtained by using the VSM. It may be noted that all values of the device 220 are measured to be less than the result of the thin film 210 or the result obtained by using the VSM, which may mean that a sample may be damaged during a photolithography process.

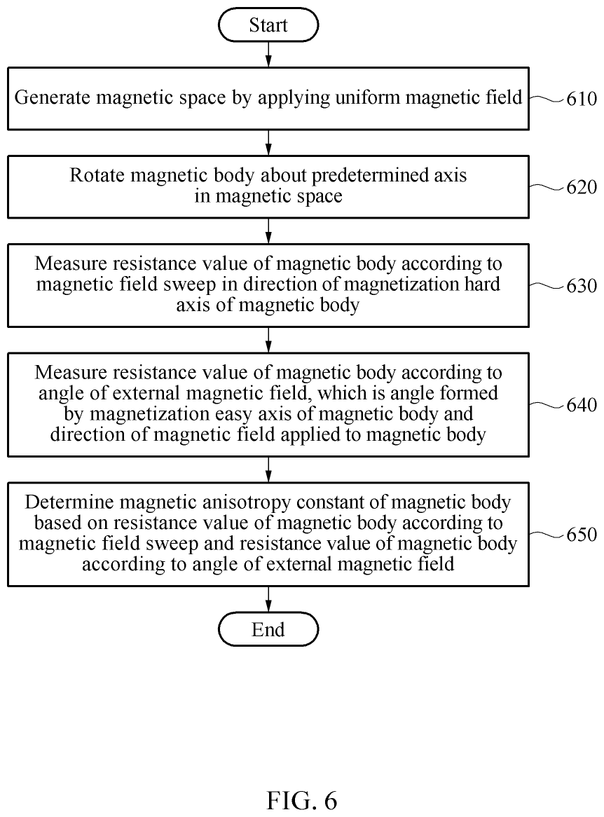

FIG. 6 illustrates an example method with magnetic anisotropy constant determination according to one or more embodiments.

For ease of description, operations 610 through 650 are described to be performed by using the apparatus 100 described with reference to FIG. 1. However, operations 610 through 650 may be performed by another suitable electronic device in any suitable system.

Furthermore, the operations of FIG. 6 may be performed in the shown order and manner. However, the order of some operations may change, or some operations may be omitted, without departing from the spirit and scope of the shown example. Many of the operations shown in FIG. 6 may be performed in parallel or simultaneously. One or more operations of FIG. 6, and combinations of the operations, can be implemented by special purpose hardware-based computer, such as a processor, that performs the specified functions, or combinations of special purpose hardware and computer instructions.

In operation 610, the apparatus 100 may generate a magnetic space by applying a uniform magnetic field.

In operation 620, the apparatus 100 may rotate a magnetic body (e.g., the sample 10 of FIG. 1) about a predetermined axis in the magnetic space.

In operation 630, the apparatus 100 may measure a resistance value of the magnetic body according to a magnetic field sweep in the direction of a magnetization hard axis of the magnetic body. The apparatus 100 may supply a predetermined current to the magnetic body through electrodes of first both ends of the magnetic body in a direction of the predetermined axis, may measure a voltage of the magnetic body through electrodes of second both ends of the magnetic body in the direction perpendicular to the predetermined axis, may measure a voltage value of the magnetic body according to the magnetic field sweep, and may determine the resistance value of the magnetic body according to the magnetic field sweep based on a current value supplied to the magnetic body and the voltage value of the magnetic body according to the magnetic field sweep.

In operation 640, the apparatus 100 may measure a resistance value of the magnetic body according to an angle of an external magnetic field, which is an angle formed by a magnetization easy axis of the magnetic body and the direction of a magnetic field applied to the magnetic body.

The apparatus 100 may supply a predetermined current to the magnetic body through electrodes of first both ends of the magnetic body in the direction of the predetermined axis, may measure a voltage of the magnetic body through electrodes of second both ends of the magnetic body in the direction perpendicular to the predetermined axis, may measure a voltage value of the magnetic body according to the angle of the external magnetic field, and may determine the resistance value of the magnetic body according to the angle of the external magnetic field based on a current value supplied to the magnetic body and the voltage value of the magnetic body according to the angle of the external magnetic field.

In operation 650, the apparatus 100 may determine the magnetic anisotropy constant of the magnetic body based on the resistance value of the magnetic body according to the magnetic field sweep and the resistance value of the magnetic body according to the angle of the external magnetic field. More particularly, the apparatus 100 may determine a first parameter based on the resistance value of the magnetic body according to the magnetic field sweep. In an example, the apparatus 100 may determine the first parameter based on a gradient in a section where the resistance value of the magnetic body according to the magnetic field sweep is unsaturated.

The apparatus 100 may determine a second parameter based on the resistance value of the magnetic body according to the angle of the external magnetic field. In an example, the apparatus 100 may determine the second parameter based on a gradient in a section determined based on the magnetization easy axis of the magnetic body.

The apparatus 100 may determine the magnetic anisotropy constant of the magnetic body based on the first parameter and the second parameter. In an example, the apparatus 100 may determine a value obtained by dividing a value of multiplying the fixed magnitude of the external magnetic field and the second parameter by a value obtained by subtracting the second parameter from a value of multiplying the fixed magnitude of the external magnetic field and the first parameter as the magnetic anisotropic constant of the magnetic body.

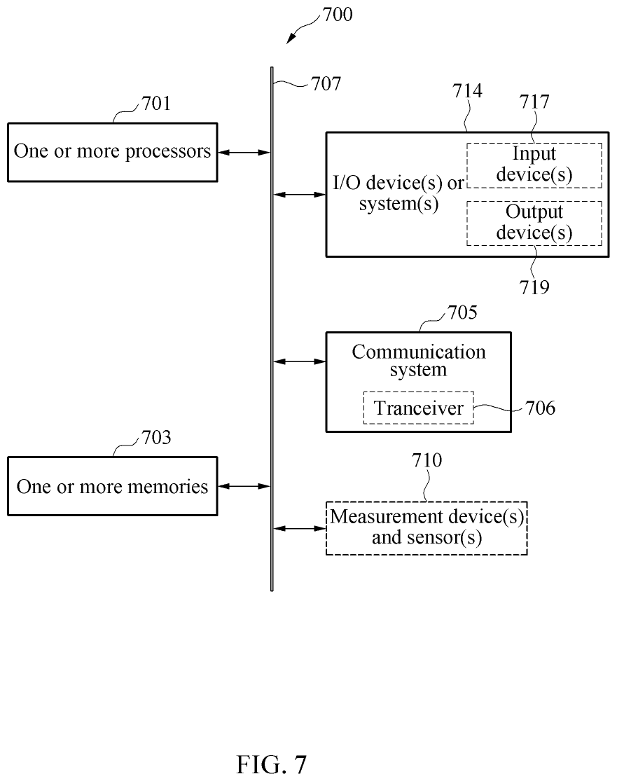

FIG. 7 illustrates an example configuration of an electronic device or system according to one or more embodiments.

Referring to FIG. 7, an electronic device (or system) 700 may include one or more processors 701, one or more memories 703, a communication system 705, and a bus 707. In an example, the electronic device 700 may include measurement device(s) and/or sensor(s) 710. As an alternative, the electronic device 700 may be an electronic system 700 that includes the measurement device(s) and/or sensor(s) 710, or the measurement device(s) and/or sensor(s) 710 may be exterior to the electronic device 700. As a non-limiting example, the electronic device may be the calculator 150 of FIG. 1, or at least one processors of the one or more processors 701 may correspond to the calculator 150.

The one or more processors 701 may perform the operations described above with reference to FIGS. 1 through 6. The one or more processors 701 may receive a resistance value (e.g., from the measurement device(s) and/or sensor(s) 710) of a magnetic body according to a magnetic field sweep in the direction of a magnetization hard axis of the magnetic body. The one or more processors 701 may receive a resistance value (e.g., from the measurement device(s) and/or sensor(s) 710) of the magnetic body according to an angle of an external magnetic field, which is an angle formed by a magnetization easy axis of the magnetic body and the direction of a magnetic field applied to the magnetic body. The one or more processors 701 may determine the magnetic anisotropy constant of the magnetic body based on the resistance value of the magnetic body according to the magnetic field sweep and the resistance value of the magnetic body according to the angle of the external magnetic field.

The one or more memories 703 may be volatile memories or non-volatile memories or the combination thereof, and the one or more memories 703 may store data and instructions that configure the one or more processors to perform any one or any combination or all of the operations described above with reference to FIGS. 1 through 6.

The communication system 705 is hardware that is configured to interface with, receive information from, and may transmit information to, the measurement device(s) and/or sensor(s) 710, another electronic device 700, and/or another server through a network. In other words, the electronic device 700 may be connected to an external device through the communication system 705 and may exchange data with the external device (e.g., the measurement device(s) and/or sensor(s) 710 that is exterior of the electronic device (or system) 700). In an example, the measurement device(s) and/or sensor(s) 710 may be the data measurement device 130 of FIG. 1 through the communication system 705.

The electronic device 700 may further include other components. For example, the electronic device 700 may further include an input/output (I/O) interface 714 including the input device(s) 716 and/or the output device(s) 719 as methods for an interface with the communication system 705. In addition, for example, the electronic device 700 may further include other components such as transceiver(s) 706 of the bus 707 and/or the communication system 705 and database(s) in one of the one or more memories 703.

The processors, memories, electronic devices, apparatuses, and other apparatuses, devices, units, models, modules, and components described herein with respect to FIGS. 1-7 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A processor-implemented method, comprising:
applying a uniform magnetic field to generate a magnetic space;
rotating a magnetic body in the magnetic space about a predetermined axis;
measuring a first resistance value;
measuring a second resistance value; and
calculating a magnetic anisotropy constant of the magnetic body, based on the first and second resistance values,
wherein the first resistance value is a measured resistance value of the magnetic body according to a magnetic field sweep in a direction of a magnetization hard axis of the magnetic body, and
wherein the second resistance value is another measured resistance value of the magnetic body according to an angle of an external magnetic field, the angle of the external magnetic field being an angle formed by a magnetization easy axis of the magnetic body and a direction of the uniform magnetic field applied to the magnetic body.

2. The method of claim 1, wherein
the calculating of the magnetic anisotropy constant of the magnetic body comprises:
determining a saturation parameter based on the first resistance value;
determining a magnetism-based parameter based on the second resistance value; and
determining the magnetic anisotropy constant of the magnetic body based on the saturation parameter and the magnetism-based parameter.

3. The method of claim 2, wherein
the determining of the saturation parameter comprises determining the saturation parameter based on a gradient in a section where the first resistance value is unsaturated.

4. The method of claim 2, wherein
the determining of the magnetism-based parameter comprises determining the magnetism-based parameter based on a gradient in a section determined based on the magnetization easy axis of the magnetic body.

5. The method of claim 2, further comprising performing
the measuring of the second resistance value according to the angle of the external magnetic field in a state in which a magnitude of the external magnetic field is fixed.

6. The method of claim 5, wherein
the magnetic anisotropy constant of the magnetic body is obtained by: multiplying the fixed magnitude of the external magnetic field and the second parameter to generate a first value;
multiplying the fixed magnitude of the external magnetic field and the first parameter to generate a second value;
subtracting the second parameter from the second value to generate a third value; and
dividing the first value by the third value.

7. The method of claim 1, further comprising performing
the measuring of the first resistance value by:
supplying a predetermined current to the magnetic body through electrodes of first both ends of the magnetic body in a direction of the predetermined axis;
measuring, according to the magnetic field sweep, a first voltage value of the magnetic body through electrodes of second both ends of the magnetic body in a direction perpendicular to the predetermined axis; and
determining the first resistance value based on a current value supplied to the magnetic body and the measured first voltage value of the magnetic body.

8. The method of claim 1, further comprising performing
the measuring of the second resistance value by:
supplying a predetermined current to the magnetic body through electrodes of first both ends of the magnetic body in a direction of the predetermined axis;
measuring, according to the angle of the external magnetic field, a second voltage value of the magnetic body through electrodes of second both ends of the magnetic body in a direction perpendicular to the predetermined axis; and
determining the second resistance value based on a current value supplied to the magnetic body and the measured second voltage value of the magnetic body.

9. The method of claim 1, wherein
the magnetic body, with an in-plane magnetic anisotropy (IMA), comprises an ultra-thin film having a thickness of 1 nanometer (nm) or less.

10. A non-transitory computer-readable storage medium storing instructions that, when executed by a processor, cause the processor to perform the method of claim 1.

11. An apparatus, comprising:
a magnetic field generator configured to generate a magnetic space by applying a uniform magnetic field;
a rotating driver configured to rotate the magnetic body about a predetermined axis in the magnetic space;
a data measurement device configured to measure a first resistance value and a second resistance value; and
a calculator configured to determine the magnetic anisotropy constant of the magnetic body based on the first resistance value and the second resistance value,
wherein the first resistance value is a measured resistance value of the magnetic body according to a magnetic field sweep in a direction of a magnetization hard axis of the magnetic body, and
wherein the second resistance value is another measured resistance value of the magnetic body according to an angle of an external magnetic field, the angle of the external magnetic field being an angle formed by a magnetization easy axis of the magnetic body and a direction of a magnetic field applied to the magnetic body.

12. The apparatus of claim 11, wherein
the calculator is configured to determine a first parameter based on the first resistance value, determine a second parameter based on the second resistance value, and determine the magnetic anisotropy constant of the magnetic body based on the first parameter and the second parameter.

13. The apparatus of claim 12, wherein
the calculator is configured to determine the first parameter based on a gradient in a section where the first resistance value is unsaturated.

14. The apparatus of claim 12, wherein
the calculator is configured to determine the second parameter based on a gradient in a section determined based on the magnetization easy axis of the magnetic body.

15. The apparatus of claim 12, wherein
the calculator is configured to measure the second resistance value according to the angle of the external magnetic field in a state in which a magnitude of the external magnetic field is fixed.

16. The apparatus of claim 15, wherein
the calculator is configured to determine the magnetic anisotropy constant of the magnetic body by:
multiplying the fixed magnitude of the external magnetic field and the second parameter to obtain a first value;
multiplying the fixed magnitude of the external magnetic field and the first parameter to obtain a second value;
subtracting the second parameter from the second value to obtain a third value; and
dividing the first value by the third value.

17. The apparatus of claim 11, wherein
the data measurement device is configured to:
supply a predetermined current to the magnetic body through electrodes of first both ends of the magnetic body in a direction of the predetermined axis;
measure, according to the magnetic field sweep, a first voltage value of the magnetic body through electrodes of second both ends of the magnetic body in a direction perpendicular to the predetermined axis; and
determine the first resistance value based on a current value supplied to the magnetic body and the measured first voltage value of the magnetic body.

18. The apparatus of claim 11, wherein
the data measurement device is configured to:
supply a predetermined current to the magnetic body through electrodes of first both ends of the magnetic body in a direction of the predetermined axis;
measure, according to the angle of the external magnetic field, a second voltage value of the magnetic body through electrodes of second both ends of the magnetic body in a direction perpendicular to the predetermined axis; and
determine the second resistance value based on a current value supplied to the magnetic body and the measured second voltage value of the magnetic body.

19. The apparatus of claim 11, wherein
the magnetic body, with an in-plane magnetic anisotropy (IMA), comprises an ultra-thin film having a thickness of 1 nanometer (nm) or less.

20. An electronic device comprising:
one or more processors configured to execute instructions; and
one or more memories storing the instructions,
wherein the execution of the instructions by the one or more processors configures the one or more processors to:
generate a first resistance value of a magnetic body according to a magnetic field sweep in a direction of a magnetization hard axis of the magnetic body;
generate a second resistance value of the magnetic body according to an angle of an external magnetic field, the angle of the external magnetic field being an angle formed by a magnetization easy axis of the magnetic body and a direction of a magnetic field applied to the magnetic body; and
determine a magnetic anisotropy constant of the magnetic body based on the first resistance value and the second resistance value.
